(19) United States
(12) Patent Application Publication
(10) Pub. No.: US 2008/0242125 A1
(43) Pub. Date: Oct. 2, 2008

(54) Large LGA socket and method of manufacture

(75) Inventors: Jeffrey G. Pennypacker, Harrisburg, PA (US); Jeffrey B. McClinton, Harrisburg, PA (US); Richard N. Whyne, Camp Hill, PA (US); Alan A. Kordas, Lewisberry, PA (US)

Correspondence Address: Robert K. Kapalka, Suite 140, 4550 Linden Hill Road, Wilmington, DE, 19808-2952, US

(73) Assignee: Tyco Electronics Corporation, Middletown, PA (US)

(21) Appl. No.: 11/732,017

(22) Filed: Apr. 2, 2007

(51) Int. Cl. H05K 1/00

(52) U.S. Cl. 439/78

(57) ABSTRACT

An LGA interconnect device, method of making, and device for making.

### BACKGROUND

The subject invention relates to a Land Grid Array (LGA) socket and a method of manufacturing the same.

Various packages or devices exist within the computer industry which require interconnection to a printed circuit board. These devices have lands or balls which are placed on 1.0-mm centerline spacing and below. These devices are profiled with arrays of 50 by 50 and even greater. Given the plurality of lands, their centerline spacing, and given the force applied to each land, this device causes a variety of problems in practice in connection to the printed circuit board.

Sockets exist within the market for the interconnection of such devices, where the sockets include columns of conductive polymer allowing the interconnection between the devices and the printed circuit boards. However, these devices too can cause some problems. For example, the conductive polymers can creep over time, and after temperature exposure and thermal cycling. Therefore, its elasticity is reduced, and the normal force, which is applied to the contact interface, is also reduced.

Additionally, LGA interconnects comprising a metal substrate and a plurality of contact assemblies comprised of at least one metal contact and an insulative member are disclosed in U.S. Pat. No. 6,945,788, the disclosure of which is incorporated herein by reference. Each of the aforementioned interconnects requires precise placement on the associated printed circuit board and precise placement of the package thereon. These and other problems are addressed by the present invention.

### SUMMARY

According to a first embodiment of the present disclosure, an LGA interconnect, is provided. The LGA interconnect comprises a substrate; and a plurality of datum structures heat staked to the substrate.

According to another embodiment of the present disclosure, a fixture for assembling an electrical component is provided. The fixture includes a base having a plurality of recesses and a substrate receiving surface, each recess sized and located to receive first pieces of the electrical component, the substrate receiving surface providing for a substrate to be received thereon so as to engage any first pieces located within the recesses; a plurality of clamps positioned to engage the first pieces of the electrical component; and a biaser associated with each clamp to urge the clamp toward the base.

According to another embodiment of the present disclosure, a method of assembling an LGA interconnect is provided. The method includes the steps of placing a substrate in contact with a plurality of datum structures; and heat staking the datum structures to the substrate.

### BRIEF DESCRIPTION OF THE DRAWINGS

FIG. 1 is a top view of an assembled Land Grid Array (LGA) interconnect socket;

FIG. 2 is a top view of the LGA interconnect socket of FIG. 1 with the package removed;

FIG. 3 is a perspective view of the underside of the LGA interconnect socket of FIG. 1;

FIG. 4 is a top perspective view of a top datum structure of the LGA interconnect socket of FIG. 1;

FIG. 5 is a bottom perspective view of a top datum structure of the LGA interconnect socket of FIG. 1;

FIG. 6 is a top perspective view of a second embodiment top datum structure of the LGA interconnect socket of FIG. 1;

FIG. 7 is a perspective view of a bottom datum structure of the LGA interconnect socket of FIG. 1;

FIG. 8 is a perspective view of the substrate of the LGA interconnect socket of FIG. 1;

FIG. 9 is a top view of an insulative housing of the substrate of the LGA interconnect socket of FIG. 1;

FIG. 10 is a perspective view of a heat staking press used to assemble the LGA interconnect of FIG. 1;

FIG. 11 is a partially exploded view of a compression probe of the press of FIG. 10;

FIG. 12 is a perspective view of a fixture of the press of FIG. 10; and

FIGS. 13a,b are perspective views of a hold down of the fixture of FIG. 12.

### DETAILED DESCRIPTION

The subject disclosure relates to a Land Grid Array (LGA) interconnect socket 2 and a method of manufacturing the same. When used herein, the term LGA is meant to define many different interconnects. For example, it could be interpreted to mean a chip interconnected to a printed circuit board. However, it can also mean a board to board interconnect. In this application, the embodiments will be described by way of an interconnect to a chip.

Additionally, although the present disclosure is exemplified in the context of an LGA socket connector 2, the present disclosure is not limited to LGA socket connectors. Rather, the present disclosure may be adapted for use as any electrical interconnect structure, including, for example, a Ball Grid Array (BGA) socket, Column Grid Array (CGA), right angle connectors and backplane connectors.

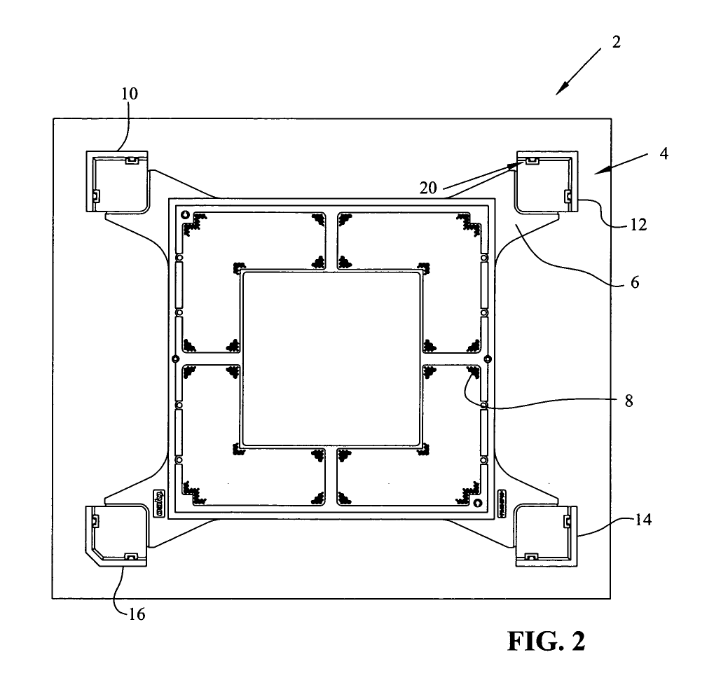

With reference first to FIG. 2, LGA interconnect 2 is shown as including datum structures 10-16, which retains and aligns a substrate 6 attached thereto, where substrate 6 holds a plurality of contact assemblies 8 in a fixed array as shown. Plurality of corner datum structures 10, 12, 14, and 16, together define an inner chip-receiving nest, generally designated herein as reference numeral 20. With the general nature of the socket as described above, the detail of the individual components and their assembly will now be described in greater detail.

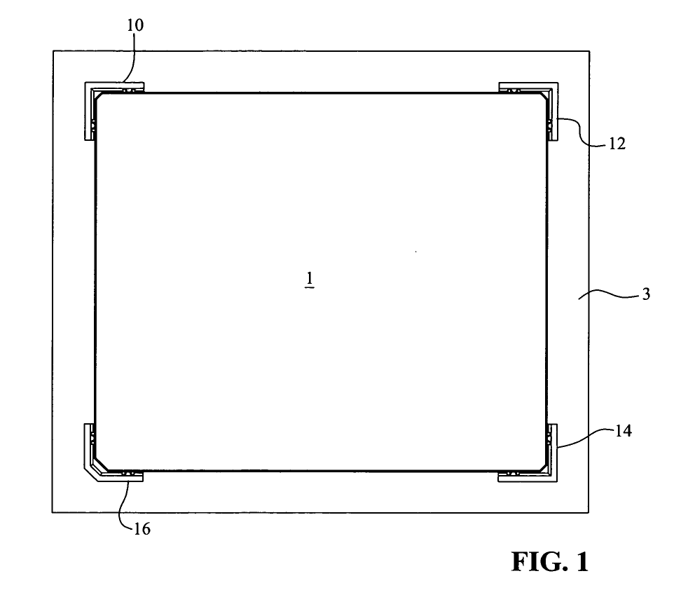

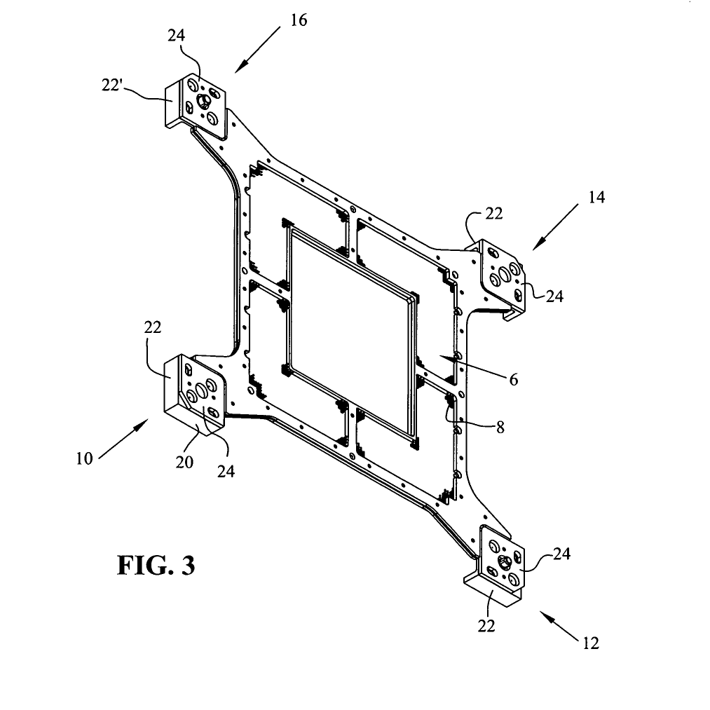

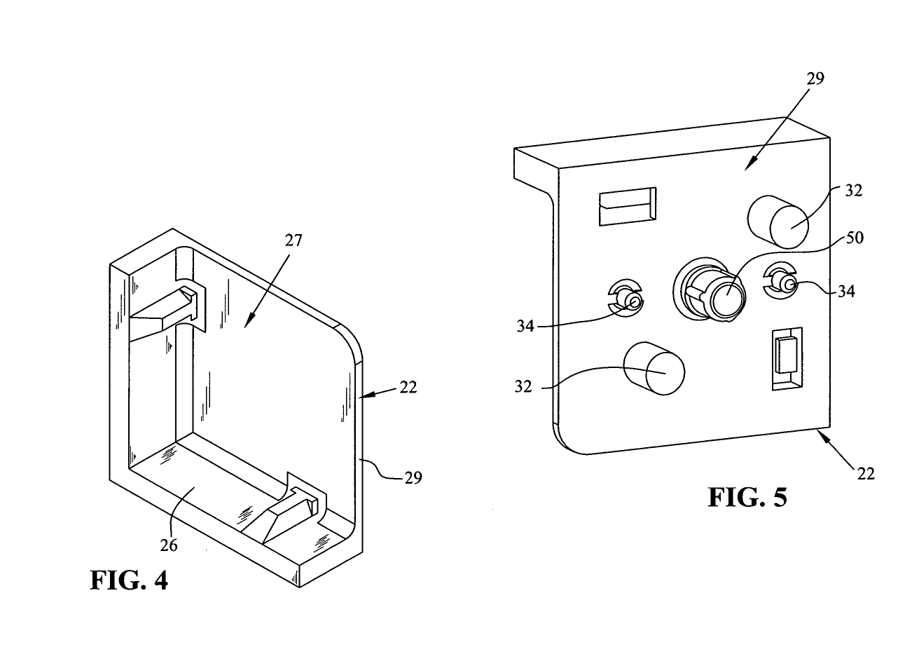

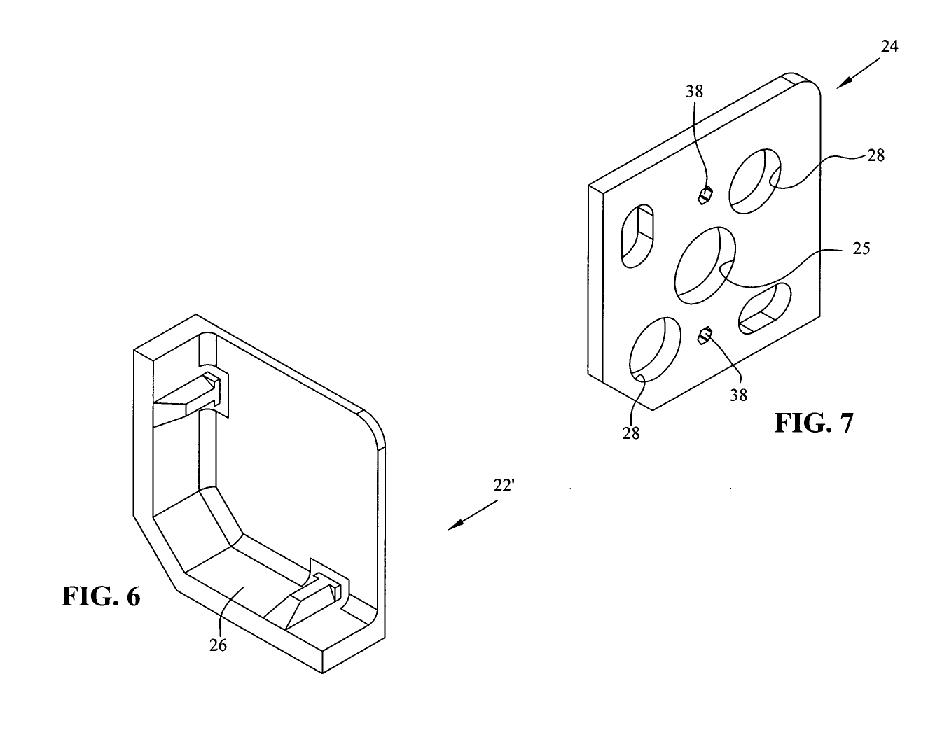

As shown in FIG. 3, each of the datum structures 10-16 includes top 22, 22′ and bottom 24. With respect to FIGS. 4 and 5, top 22 of datum structure 10 is shown without substrate 6. Each top 22, 22′ includes walls 26. Top 22, 22′ includes upper side 27 and underside 29. Whereas upper sides 27 of tops 22 of datum structures 10, 12, 14 include walls 26 that substantially form a 90-degree corner, walls 26 of top 22′ of orienting/polarizing datum structure 16 include two 45-degree corners, see FIG. 6. This difference in wall 26 structure provides polarization for the package 1 to be received thereby, as shown in FIG. 1.

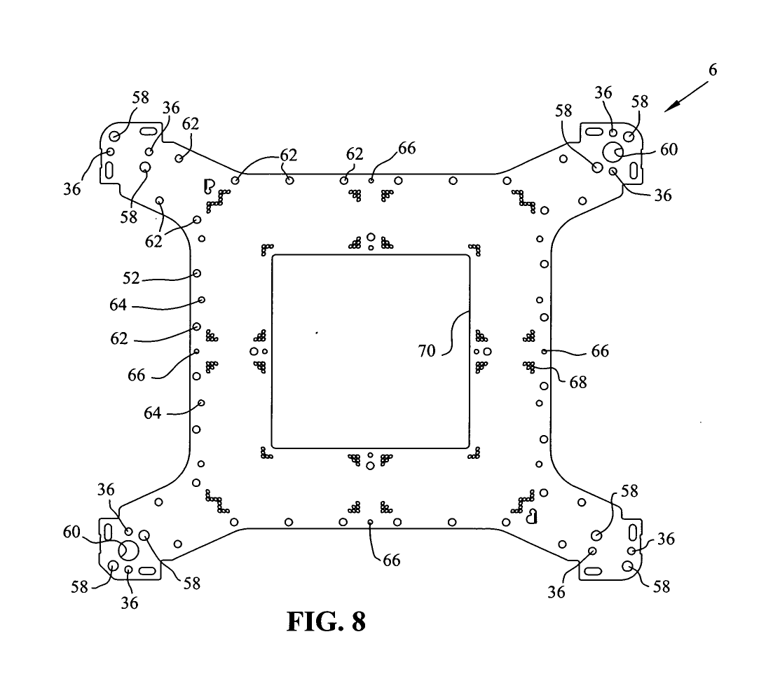

Underside 29 of each top 22, 22′ includes posts 32, pins 34, and optionally aligning lug 50. Pair of posts 32 are sized and located to be received within corner portion of substrate 6, discussed below. Pins 34 also extend through apertures 36 (FIG. 8) in the corner of substrate 6 and are received by mating apertures 38 (FIG. 7) defined in bottom 24. Bottom 24, as shown in FIG. 7, also includes post apertures 28 and lug aperture 25. When assembled with respective tops 22, 22′, posts 32 in their heat staked form, are located within post apertures 28 and aligning lugs 50 extend through lug apertures 25 where present.

Tops 22, 22′ of datum structures 12, 16 each include aligning lug 50. It should be noted, however, that datum structures 10 and 14 do not have lugs 50 for polarizing purposes, as will also be described further herein, see FIG. 3.

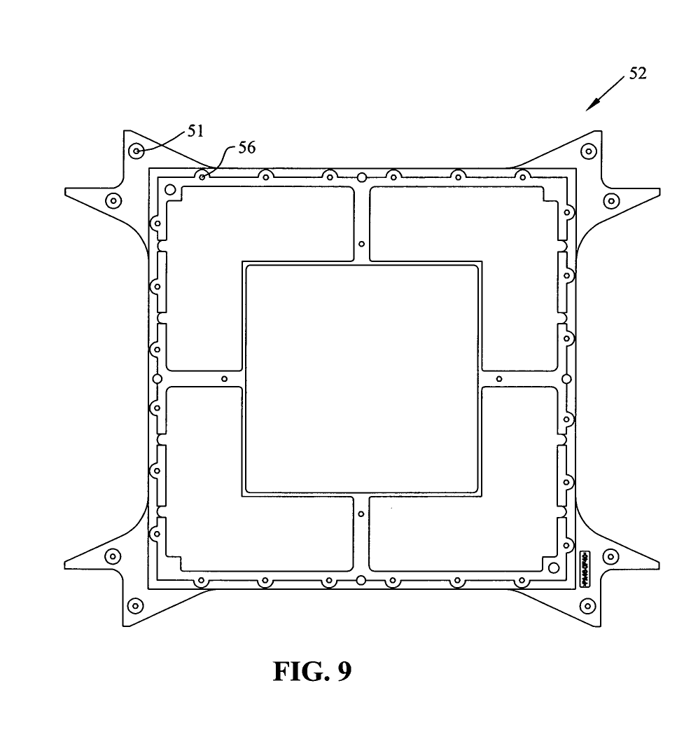

With reference now to FIG. 8, substrate 6 is shown in greater detail. As shown, substrate 6 generally approximates an “X.” Each corner spoke of substrate 6 is profiled to receive a respective datum structure 10-16. Substrate 6 is formed from stainless steel and includes frame housing portions 52 on either side thereof, FIG. 9. Substrate 6 is a stamped or etched substantially-flat sheet that includes many apertures therein. Such apertures include apertures 36, 58, 60 for pins 34, posts 32, and lugs 50. Such apertures also includes apertures 62, 64, 66 for posts 51 of housing portions 52, fixture bolts 260, and for pilot pins 236 of fixture 206, as discussed below, respectively. Substrate 6 also includes array of apertures 68 for receiving contact assemblies 8 and includes central aperture 70.

With the above-mentioned components as described, the method of manufacturing the components can now be described. With respect first to FIG. 8, substrates 6 shown. As previously noted, substrate 6 is produced from stainless steel in order to define a rigid substrate. However, other materials could be used as alternatives, such as ceramics, plastics, or other sufficiently rigid materials.

As shown in FIG. 8, the majority of the detail of the edges, apertures (36, 58, 60, 62, 64, 68, 70), and pilot pin apertures 66 can be produced by an etching process, which provides dimensions having extremely tight tolerances. It should be appreciated that etched substrates 6 as shown in FIG. 8 can be further processed whereby the contacts can be loaded. The etching process can also produce a flat strip of material, not subject to the forces of the stamping process.

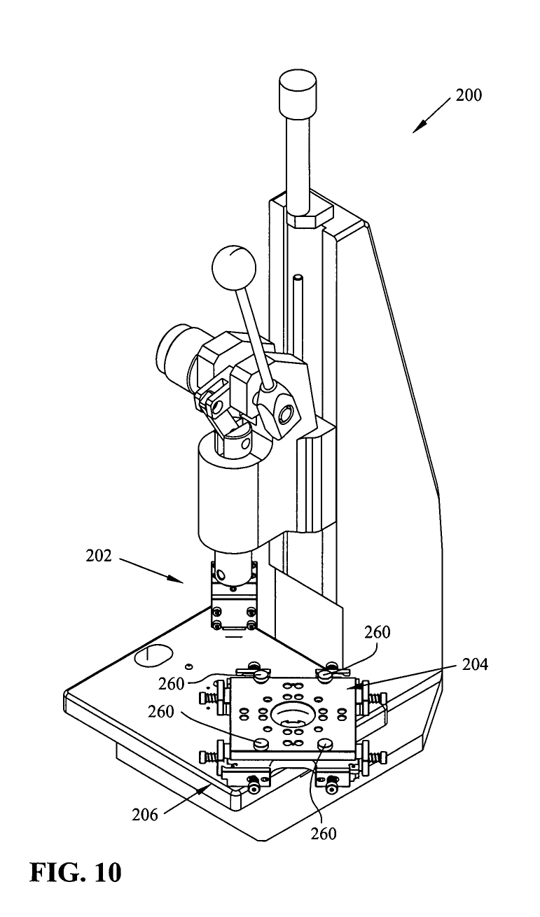

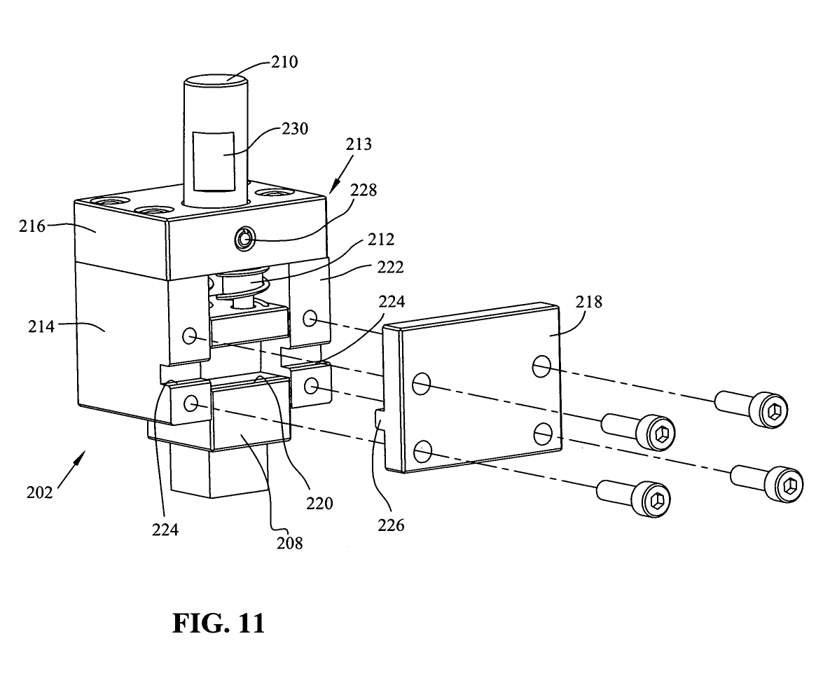

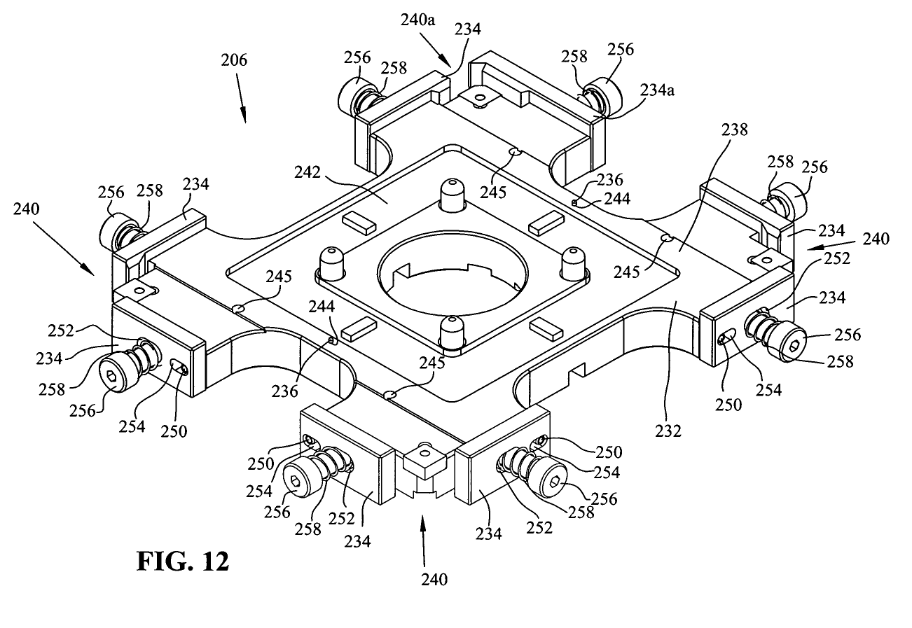

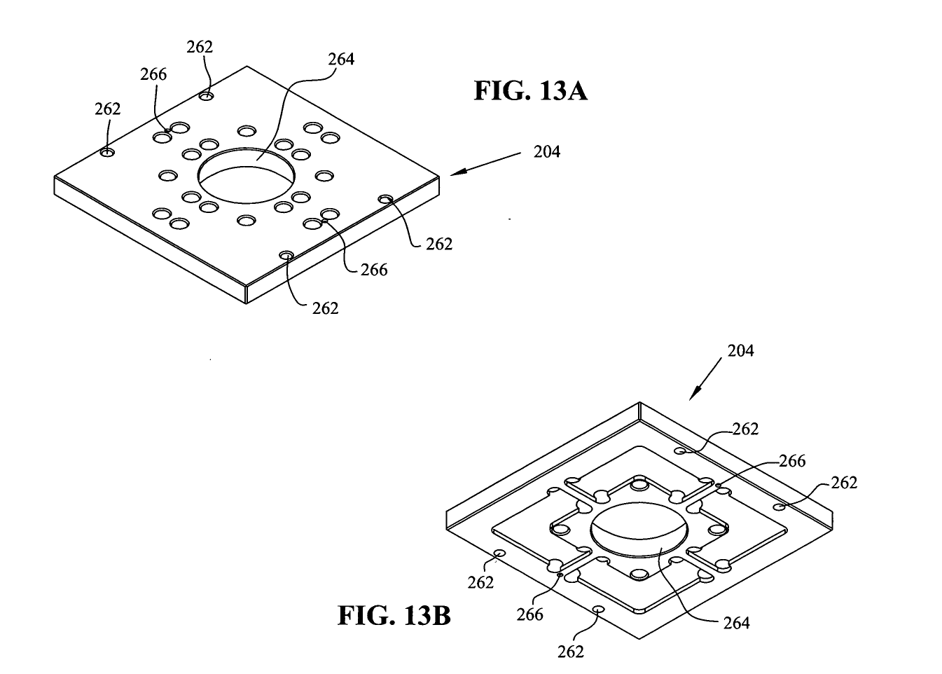

Once prepared, via etching or otherwise, substrates 6 are assembled into LGA interconnect 2 via heat staking press 200, shown in FIG. 10. Press 200 includes compression probe 202, shown in FIG. 11, substrate hold down 204, shown in FIGS. 13a, 13b, and fixture 206, shown in FIG. 12. As shown in FIG. 11, compression probe 202 includes pressure pad 208, ram adapter 210, staking punches 212, pressure pad retainer 214, pressure pad back up plate 216, and pressure pad clamp 218. Pressure pad 208 includes bores therein that receive staking punches 212 therein. Pressure pad 208 also includes a lateral cut out 220. Pressure pad 208 is received within housing 213 formed from pressure pad retainer 214, pressure pad back up plate 216, and pressure pad clamp 218. Pressure pad retainer 214 includes clamp surfaces 222 that each include lateral cut outs 224 having height and depth dimensions similar to lateral cut out 220. When assembled, cut outs 220, 224 align and receive alignment surface 226 of pressure pad clamp 218 therein. Pressure pad retainer 214, pressure pad back up plate 216, and pressure pad clamp 218 are all coupled together via hex drive bolts to form housing 213. Ram adapter 210 couples to housing 213 via pin 228. Ram adapter 210 includes a void (not shown) to receive pin 228 and a recessed portion 230 that engages an end of a bolt to couple ram adapter 210 to the rest of press 200.

Fixture 206 includes base 232, a plurality of clamps 234, 234a, and pilot pins 236. Base 232 includes an upward facing substrate receiving surface 238. Substrate receiving surface 238 includes a plurality of depressions and bores defined therein. Main depression 242 is sized and shaped to substantially align with the contact assembly area of substrate 6 when substrate 6 is received thereon. Pilot bores 244 are sized to partially receive pilot pins 236 therein. Bolt bores 245 are sized to receive threaded portions of bolts 260. Corners 240, 240a of base 232 include cut-outs sized and shaped to receive tops 22, 22′ of datum structures 10-16 therein. Lateral edges of base 232 include a plurality of bolt bores (not shown) and respective pin bores (not shown) proximate corners 240, 240a. Pins 250 partially engage the pin bores.

Clamps 234, 234a are coupled to lateral edges of base 232 proximate corners 240, 240a. Each clamp 234, 234a includes bolt bore 252 and pin bore 254. Bolts 256 engage springs 258, bolt bores 252, and bolt bores (not shown) in fixture 206 to couple each clamp 234, 234a to base 232. Similarly, pin bores 254 align with and receive pins 250 to properly orient clamps 234, 234 on base 232. Accordingly, clamps 234, 234a are biased via springs 258 toward base 232. It should be appreciated that clamp 234a is located at corner 240a. Orienting clamp 234a is slightly different than clamps 234 in that it is shaped to receive orienting datum structure 16 that includes two 45-degree corners. In embodiments that utilize aligning lugs 50, associated PCB's 3 have precisely located apertures for receiving lugs 50. Additionally, whereas springs 258 and bolts 256 are shown, any connection of clamps 234, 234a that biases toward base 232 to achieve the assembly functionality discussed below, may be utilized.

Substrate hold down 204 is a removable piece of fixture 206. Hold down 204 is a substantially flat rigid piece of metal sized and shaped to selectively couple to base 232 to secure substrate 6. Hold down 204 includes relatively large central aperture 264, bolt apertures 262, and pilot apertures 266. Bolt apertures 262 are sized to receive bolts 260 therein. Bolts 260 include shoulders, not shown, that engage upper surface 270 of hold down 204 when assembled. Pilot apertures 266 are sized, shaped, and located to receive pilot pin 236 therein when coupled to fixture 206.

Having described the various parts of LGA interconnect 2 and press 200, the use of press 200 to assemble LGA interconnect 2 will now be described. In use, tops 22, 22′ of datum structures 10-16 are first placed in respective corners 240, 240a of base 232 with the undersides 29 facing upwards. Walls 26 of datum structures 10-16, when so placed, are contacted by clamps 234, 234a. Springs 258 urge clamps 234, 234a into contact with walls 26 of datum structures 10-16. This contact and further pressure applied by springs 258 urge datum structures 10-16 to abut base 232 and urge datum structures 10-16 into the proper position. Once tops 22, 22′ of datum structures 10-16 are properly located, etched or otherwise cut substrate 6 is lowered onto base 232. Substrate 6 is oriented such that pilot pin apertures 66 align with pilot pins 236 and such that the proper corner spoke is received within orienting datum structure 16. This positioning also places posts 32, pins 34, and aligning lug 50 within respective apertures 58, 36, 60.

Once properly positioned, substrate hold down 204 is lowered to abut and fix the position of substrate 6 relative to fixture 206 and tops 22, 22′ of datum structures 10-16. Bolts 260 extend through apertures 262 in hold down 204 and bolt bores 245 in fixture 206 to fix hold down 204 and substrate 6 to fixture 206. Next, the fixture 206, substrate 6, datum structures 10-16, and hold down 204 combination are positioned relative to compression probe 202 such that staking punches 212 align with posts 32. Staking punches 212 are heated. Lowering of compression probe 202 causes abutment of staking punches 212 and posts 32. This abutment causes posts 32 to be deformed through the softening of the plastic to form a head which mechanically locks the tops 22, 22′ and substrate 6 together. This process is repeated for each datum structures 10-16, or performed simultaneously for all datum structures 10-16.

Once mechanically locked, the relative position of substrate 6 and datum structures 10-16 is fixed. Next, each bottom 24 is placed in contact with substrate 6. Pins 34 engage apertures 38 to hold bottom 24 thereto by friction fit or otherwise.

The assembled combination of substrate 6 and plurality of corner datum structures 10 is then removed from the fixture. Insulative housings 4 are later applied to each side. One housing 4 has posts that extend through substrate 6 and engage apertures in a mating housing 4 on the opposite side of substrate 6 to couple housings 4 to substrate 6.

Either before or after the application of housings 4, contact assemblies 8 are coupled to substrate 6. Once housings 4 and contact assemblies 8 are coupled to substrate 6, interconnect socket 2 is completed and ready to engage a package 1 and PCB 3.

By tightly controlling the relative position of walls 26 of datum structures 10-16 and substrate 6, it is assured that contact/pads of the package 1 received in LGA interconnect 2 are properly aligned with the contact assemblies 8. Similarly, the tight position control dictates the relative position of aligning lugs 50 to substrate 6 such that contact assemblies 8 are properly aligned with contacts on an associated PCB 3.

What is claimed is:

1. An LGA interconnect, comprising:
a substrate; and
a plurality of datum structures heat staked to the substrate.

2. The LGA interconnect of claim 1, wherein the plurality of datum structures includes a polarizing datum structure.

3. The LGA interconnect of claim 1, wherein the substrate includes a plurality of apertures therethrough arranged in an array.

4. The LGA interconnect of claim 3, wherein the datum structures include walls that define a pre-determined relationship relative to the plurality of apertures.

5. The LGA interconnect of claim 1, wherein the pre-determined relationship is based on the distance between an outer perimeter and contacts of a package to be received by the interconnect.

6. The LGA interconnect of claim 1, wherein the datum structures have a pre-determined location relative to the substrate.

7. The LGA interconnect of claim 1, wherein at least one of the datum structures includes an aligning lug.

8. The LGA interconnect of claim 7, wherein the aligning lug is sized and shaped to be received by a PCB.

9. The LGA interconnect of claim 1, wherein the substrate is comprised of metal.

10. The LGA interconnect of claim 1, wherein the substrate includes pilot apertures therein.

11. A fixture for assembling an electrical component including:
a base having a plurality of recesses and a substrate receiving surface, each recess sized and located to receive first pieces of the electrical component, the substrate receiving surface providing for a substrate to be received thereon so as to engage any first pieces located within the recesses;
a plurality of clamps positioned to engage the first pieces of the electrical component; and
a biaser associated with each clamp to urge the clamp toward the base.

12. The fixture of claim 11, further including pilot pins coupled to the base.

13. The fixture of claim 11, wherein the plurality of clamps includes at least one orienting clamp.

14. The fixture of claim 11, wherein the biaser is a spring.

15. The fixture of claim 11, wherein the base includes a plurality of threaded bores.

16. The fixture of claim 11, further including a hold down plate.

17. A method of assembling an LGA interconnect including the steps of:
placing a substrate in contact with a plurality of datum structures; and
heat staking the datum structures to the substrate.

18. The method of claim 17, further including the steps of:
providing a fixture, and
placing the datum structures in contact with the fixture so as to cause the datum structures to engage clamps that urge the abutment of the datum structures to the fixture.

19. The method of claim 18, further including the step of placing the substrate in contact with the fixture including engaging pilot pins of the fixture into pilot holes of the substrate.

20. The method of claim 18, further including the step of coupling a hold down plate to the fixture.
